(19) United States
(12) Patent Application Publication
(10) Pub. No.: US 2021/0202783 A1
(43) Pub. Date: Jul. 1, 2021

(54) CRYSTALLINE SILICON SOLAR CELL AND PREPARATION METHOD THEREOF

(71) Applicants: Zhejiang Aiko Solar Energy Technology Co., Ltd., Yiwu (CN); Guangdong Aiko Solar Energy Technology Co., Ltd., Foshan (CN)

(72) Inventors: Huimin WU, Yiwu (CN); Xiaoming ZHANG, Yiwu (CN); Jiebin FANG, Yiwu (CN); Kang-Cheng LIN, Yiwu (CN); Gang CHEN, Yiwu (CN)

(21) Appl. No.: 17/203,788

(22) Filed: Mar. 17, 2021

Related U.S. Application Data
(63) Continuation-in-part of application No. PCT/CN2019/098437, filed on Jul. 30, 2019.

(30) Foreign Application Priority Data
Sep. 17, 2018 (CN) 201811081406.1

(51) Int. Cl. H01L 31/18; H01L 31/068; H01L 31/0216

(52) U.S. Cl. CPC H01L 31/182; H01L 31/02168; H01L 31/068

(57) ABSTRACT

The disclosure provides a method for preparing a crystalline silicon solar cell. The method includes: (1) forming a textured surface on a front face of a silicon wafer; (2) depositing a tunneling layer and a doped polysilicon layer on the textured surface of the silicon wafer; (3) depositing a first anti-reflection film layer on the front face of the silicon wafer; and (4) removing the tunneling layer by a laser, the doped polysilicon layer, and the first anti-reflection film layer from a non-electrode region on the front face of the silicon wafer.

### CROSS-REFERENCE TO RELAYED APPLICATIONS

This application is a continuation-in-part of International Patent Application No. PCT/CN2019/098437 with an international filing date of Jul. 30, 2019, designating the United States, now pending, and further claims foreign priority benefits to Chinese Patent Application No. 201811081406.1 filed on Sep. 17, 2018. The contents of all of the aforementioned applications, including any intervening amendments thereto, are incorporated herein by reference. Inquiries from the public to applicants or assignees concerning this document or the related applications should be directed to: Matthias Scholl PC., Attn.: Dr. Matthias Scholl Esq., 245 First Street, 18th Floor, Cambridge, Mass. 02142.

### BACKGROUND

The disclosure relates to the field of crystalline silicon solar cells, and more particularly, to a selective passivation contact crystalline silicon solar cell and a preparation method thereof.

Due to the continuous decrease in the thickness of silicon wafers in crystalline silicon cells, and for cells with a specific thickness, when the diffusion length of a minority of carriers is greater than the thickness of the silicon wafer, the surface recombination velocity has particularly significant impact on the efficiency of the solar cell. Therefore, most of existing technologies are to passivate the surface of crystalline silicon. Specifically, the backside passivation technology is to deposit a silicon nitride film on the back of a cell to reduce the back recombination velocity and effectively alleviate the problem of contact recombination between crystalline silicon and metal on the back face and improve the efficiency of the cell. Therefore, the backside passivation technology can greatly improve the efficiency of crystalline silicon solar cells.

The success of the backside passivation technology provides a feasible way to improve the efficiency of solar cells, that is, to passivate the front face of solar cells. At present, mainstream passivation technologies are to deposit a silicon nitride passivation film on the front face of the cell to alleviate the recombination problem. An advanced technology is to use the tunneling oxide layer passivation contact technology (TOPCon). In the passivation tunneling technology, an n-type silicon wafer is used as a substrate, and a tunneling layer is first deposited on the front and back faces of the silicon wafer, and then is covered by a thin-film silicon layer, thus forming tunneling oxide layer passivation contact.

The tunneling oxide layer passivation technology can form a tunneling film between the electrode and the substrate, isolate the metal electrode from coming into contact with the substrate, reduce contact recombination loss, and enable electrons to tunnel through the film without affecting current transfer. In addition, passivation can bend the surface energy band and reduce surface recombination loss of P-type silicon wafers, thus effectively alleviating front passivation and metal contact problems. However, the thin-film silicon layer arranged on the tunneling oxide layer generally has a strong light absorption capability, which reduces the output efficiency of the cell, and thus affects the efficiency of solar cells. Therefore, researchers are focusing on how to develop a passivation contact crystalline silicon solar cell that can not only utilize the advantages of the passivation contact technology, but also avoid the problem of current decrease caused by the absorption capability of the crystalline silicon film, so as to improve the conversion efficiency of the cell.

### SUMMARY

In view of the previous description, to resolve a technical problem, the disclosure provides a selective passivation contact crystalline silicon solar cell and a preparation method thereof, to effectively utilize advantages of passivation and reduce surface recombination without affecting light absorption on a surface of the solar cell or decreasing a surface current.

In another aspect, the disclosure provides a selective passivation contact crystalline silicon PERC cell with high conversion efficiency.

The disclosure provides a method for preparing a crystalline silicon solar cell, the method comprising:

(1) forming a textured surface on a front face of a silicon wafer;

(2) depositing a tunneling layer and a doped polysilicon layer on the textured surface of the silicon wafer;

(3) depositing a first anti-reflection film layer on the front face of the silicon wafer; and

(4) removing the tunneling layer by a laser, the doped polysilicon layer, and the first anti-reflection film layer from a non-electrode region on the front face of the silicon wafer. In an embodiment, (4) can be performed using a laser.

The method for preparing a crystalline silicon solar cell further comprises:

(5) forming a textured surface on the front face of the silicon wafer again;

(6) performing phosphorus diffusion on a surface of the silicon wafer;

(7) removing a PN junction on a back face and a periphery of the silicon wafer and phosphosilicate glass on the front face;

(8) depositing a passivation film on the back face of the silicon wafer;

(9) depositing a second anti-reflection film layer on the front face of the silicon wafer;

(10) performing laser perforation on the back face of the silicon wafer;

(11) etching back electrode paste and aluminum paste on the back face of the silicon wafer; and etching positive electrode paste on the front face of the silicon wafer and drying;

(12) sintering the silicon wafer obtained in 11) at a temperature of 700-950° C., to form a back electrode, an aluminum back electric field, and a positive electrode and obtain a selective passivation contact crystalline silicon solar cell product.

In a class of this embodiment, the tunneling layer is an SiO₂ layer with a thickness of 0.5-8 nm; a thickness of the doped polysilicon layer is 5-250 nm, particularly 20-100 nm.

In a class of this embodiment, a thickness of the tunneling layer is 0.5-3 nm; a thickness of the doped polysilicon layer is 50-150 nm, particularly 50-80 nm.

In a class of this embodiment, after 2) is completed, sheet resistance of the silicon wafer is 40-160 Ω/sq, particularly 40-80 Ω/sq.

In a class of this embodiment, in 3), the first anti-reflection film layer is deposited using a plasma chemical vapor deposition method; the first anti-reflection film layer is a silicon nitride film layer with a thickness of 10-100 nm, particularly 10-40 nm.

In a class of this embodiment, the positive electrode is in contact with the tunneling layer through the doped polysilicon layer, the first anti-reflection film layer, and the second anti-reflection film layer.

In a class of this embodiment, the silicon wafer is a P-type monocrystalline silicon wafer; the doped polysilicon layer is a phosphorus-doped N⁺ type polysilicon layer.

In a class of this embodiment, a mixed solution of NaOH, Na₂SiO₃, and isopropanol is used to etch the surface of the silicon wafer to prepare a textured surface.

Correspondingly, the disclosure further provides a crystalline silicon solar cell, comprising: a silicon wafer; an anti-reflection film layer and a positive electrode arranged on a front face of the silicon wafer; and a passivation film, a back electrode, and a back electric field arranged on a back face of the silicon wafer.

A tunneling layer, a doped polysilicon layer, and an anti-reflection film layer are arranged between the positive electrode and the silicon wafer; the crystalline silicon solar cell is prepared using the foregoing preparation method. The disclosure further provides a crystalline silicon solar cell, comprising: a silicon wafer; and an anti-reflection film layer and a positive electrode arranged on a front face of the silicon wafer. A tunneling layer, a doped polysilicon layer, and an anti-reflection film layer are arranged between the positive electrode and the silicon wafer. In a region having no positive electrode on the front face of the silicon wafer, the anti-reflection film layer is in direct contact with the silicon wafer.

In a class of this embodiment, the crystalline silicon solar cell further comprises: a passivation film, a back electrode, and a back electric field arranged on a back face of the silicon wafer.

In a class of this embodiment, the tunneling layer is an SiO₂ layer with a thickness of 0.5-8 nm; a thickness of the doped polysilicon layer is 5-250 nm. Particularly, a thickness of the tunneling layer is 0.5-3 nm; a thickness of the doped polysilicon layer is 50-150 nm.

In a class of this embodiment, the anti-reflection film layer is deposited using a plasma chemical vapor deposition method, and the anti-reflection film layer is a silicon nitride film layer.

In a class of this embodiment, the silicon wafer is a P-type monocrystalline silicon wafer; the doped polysilicon layer is a phosphorus-doped N⁺ type polysilicon layer.

In a class of this embodiment, the passivation film comprises an aluminum oxide film and a silicon nitride film, and the aluminum oxide film is arranged between the silicon wafer and the silicon nitride film.

In a class of this embodiment, the passivation film comprises an opening, and the back electric field is in contact with the silicon wafer through the opening.

According to the disclosure, a selective passivation contact crystalline silicon solar cell is prepared through the following processes: front-face texturing; depositing a tunneling layer, a doped polysilicon layer, and an anti-reflection film layer on the front face; front-face film removal; front-face texturing; diffusion; etching; depositing a passivation film on the back face; depositing an anti-reflection film on the front face; back-face perforation; electrode etching; and sintering. The following advantages are associated with the crystalline silicon solar cell and a preparation method thereof of the disclosure:

1. The disclosure uses the preparation methods of texturing, deposition, and laser removal, thus effectively ensuring that the passivation tunneling layer is selectively deposited in the positive electrode region, and effectively exerting a passivation effect. In addition, a non-electrode region is not blocked, thus reducing a degree to which a conventional doped silicon layer absorbs solar energy, and improving the efficiency of a solar cell.

2. The disclosure uses the passivation tunneling technology to deposit a silicon dioxide layer between the silicon wafer and the positive electrode. The passivation tunneling technology bends the energy band and block movement of an electron hole toward the front face. However, a majority of carrier electrons tunnels through the silicon dioxide layer, thus separating electrons and electron holes, reducing the loss of a fill factor, and improving the efficiency of a solar cell.

### DESCRIPTION OF EMBODIMENTS

To further illustrate, embodiments detailing a crystalline silicon solar cell and a preparation method thereof are described below. It should be noted that the following embodiments are intended to describe and not to limit the disclosure.

The disclosure provides a method for preparing a selective passivation contact crystalline silicon solar cell, the method comprising:

(1) Form a textured surface on a front face of a silicon wafer.

The silicon wafer is cleaned to remove an organic matter and a damaged layer on the surface; then a texturing operation is performed; specifically, the wet etching technology is used to form a textured surface on the front face of the silicon wafer; in an example, after texturing, a weight of the silicon wafer is reduced by 0.55-0.85 g, and reflectivity of the silicon wafer is 10.5%-11.5%. Controlling the reflectivity of the silicon wafer after texturing is conducive to controlling reflectivity of a solar cell with respect to sunlight at a later stage, thus effectively increasing an absorption rate of the solar cell with respect to sunlight, and improving the conversion efficiency of the solar cell.

(2) Deposit a tunneling layer and a doped polysilicon layer on the textured surface of the silicon wafer.

The tunneling layer is a silicon dioxide layer. The tunneling layer effectively separates electrons and electron holes, reduces the loss of a surface fill factor, and improves the efficiency of a solar cell. In an example, a thickness of the tunneling layer is 0.5-8 nm; a thickness of the doped polysilicon layer is 5-250 nm, particularly 20-100 nm; the tunneling layer and the doped polysilicon layer within these thickness ranges effectively ensure the transmission of electrons and improve the efficiency of a solar cell. In another example, a thickness of the tunneling layer is 0.5-5 nm, particularly 0.5-3 nm; a thickness of the doped polysilicon layer is 50-200 nm, particularly 50-150 nm, further particularly 50-100 nm, or even particularly 50-80 nm; the polysilicon layer and the tunneling layer within these thickness ranges better exert a passivation effect, improve the efficiency of a solar cell, and at the same time, reduce the difficulty of deposition.

In an embodiment, the tunneling layer and the doped polysilicon layer are deposited on the surface of the silicon wafer by using the low pressure chemical vapor deposition (LPCVD) method; the low pressure chemical vapor deposition method is used to deposit a uniformly thick and bonded silicon dioxide layer on the silicon wafer substrate through chemical reaction at a relatively low temperature; a reaction temperature is less than 500° C.; a deposition speed is high and energy is saved; the low pressure chemical vapor deposition method is used to prepare a dense tunneling layer and a doped polysilicon layer thereby improving the efficiency of a solar cell at a later stage.

In an example, after the tunneling layer and the doped polysilicon layer are deposited, sheet resistance of the silicon wafer is 40-160 Ω/sq, particularly 40-120 Ω/sq, or further particularly 40-80 Ω/sq; depositing a tunneling layer and a doped polysilicon layer on the surface can effectively reduce the sheet resistance of the silicon wafer, making the ohmic contact between the positive electrode and the silicon wafer substrate more sufficient, and improving the conversion efficiency of a solar cell.

(3) Deposit an anti-reflection film layer on the front face of the silicon wafer.

The anti-reflection film layer comprises silicon nitride material, and silicon nitride (SiNₓ) effectively reduces the reflection of sunlight on the surface of the silicon wafer and improves the absorption of sunlight, thereby improving the efficiency of a solar cell. In addition, the silicon nitride film achieves a good passivation effect, that is, the I-Voc is improved by 30 mV. For example, the disclosure uses a plasma chemical vapor deposition method to deposit an anti-reflection film layer on the front face of the silicon wafer. In an example, a thickness of the anti-reflection film is 10-100 nm, particularly 20-80 nm, or further particularly 20-40 nm; recombination of the silicon dioxide tunneling layer, the doped polysilicon layer, and the silicon nitride layer allows the front face of the silicon wafer to achieve a good passivation effect, while ensuring the effective transmission of carriers and improving the efficiency of a solar cell.

(4) Remove the tunneling layer, the doped polysilicon layer, and the anti-reflection film layer in a non-electrode region on the front face of the silicon wafer by using a laser.

For example, a DR laser cutting machine is used to cut the tunneling layer, the doped polysilicon layer, and the anti-reflection film layer in the non-electrode region on the front face of the silicon wafer, so as to remove the tunneling layer, the doped polysilicon layer, and the anti-reflection film layer in the non-electrode region. After this step, a selective passivation contact film is formed in the positive electrode region of the solar cell. The selective passivation contact film removes the doped polysilicon layer in the non-electrode region, reduces the absorption of sunlight by the polysilicon layer in the non-electrode region, and improves the efficiency of a solar cell.

It should be noted that the conventional tunneling oxide layer passivation contact technology is to cover a complete tunneling layer and a complete doped silicon film layer on the surface of the cell. This arrangement allows the doped silicon film layer to absorb a lot of sunlight and reduces the efficiency of a solar cell. The disclosure has developed a process of removing a passivation film in the non-electrode region, retaining the passivation film only in the electrode region to form a selective passivation contact film. The process of the disclosure achieves the purpose of effectively passivating the positive electrode region without affecting light absorption, thus effectively improving the efficiency of a solar cell.

The method for preparing a crystalline silicon solar cell further comprises:

(5) Form a textured surface on the front face of the silicon wafer again.

Specifically, the wet etching technology is used to form a textured surface on the front face of the silicon wafer; forming a textured surface again effectively removes a damaged layer generated in 4), while preparing the textured surface to reduce the reflectivity of the crystalline silicon surface. In an example, a weight of the silicon wafer is reduced by 0.15-0.35 g during the texturing. Controlling the reduction of the weight of the silicon wafer during texturing effectively controls the reflectivity of the silicon wafer after texturing. Controlling the reflectivity of the silicon wafer after texturing is conducive to controlling reflectivity of a solar cell with respect to sunlight at a later stage, thus effectively increasing an absorption rate of the solar cell with respect to sunlight, and improving the conversion efficiency of the solar cell.

In an embodiment, a mixed solution of NaOH, Na₂SiO₃, and isopropanol is used to etch the surface of the silicon wafer to prepare a textured surface. The wet etching texturing technology is divided into the use of an acidic solution to etch silicon wafers and the use of an alkaline solution to etch silicon wafers. The use of an alkaline solution for texturing prevents the reaction with the selective passivation film that has been formed, and ensures the integrity of the selective passivation film in the positive electrode region.

(6) Perform phosphorus diffusion on a surface of the silicon wafer.

Phosphorus diffusion is performed on the surface of the silicon wafer by using the low surface concentration diffusion process technology. In an embodiment, a conventional silicon wafer that has undergone 5) is used as a reference wafer to monitor the change of the silicon wafer in the phosphorus diffusion process. After phosphorus doping, sheet resistance of the reference wafer is 100-160 Ω/sq, particularly 120-160 Ω/sq. Increasing sheet resistance of the silicon wafer reduces the surface doping concentration, thus improving the shortwave effect of the cell and increase the short-circuit current, reducing the dark saturation current caused by surface recombination, and increasing the open-circuit voltage, thereby optimizing the cell performance.

(7) Remove a PN junction on a back face and a periphery of the silicon wafer and phosphosilicate glass on the front face.

An HF solution is used to remove the PN junction generated on the back face and the periphery of the silicon wafer, and at the same time, remove the phosphosilicate glass generated on the front face of the silicon wafer.

(8) Deposit a passivation film on the back face of the silicon wafer.

The passivation film is a laminated passivation film. Specifically, the passivation film is a two-layer film. The layer near the silicon wafer substrate is an aluminum oxide film, and the second layer is a silicon nitride film. The PECAD method is used to deposit the passivation film. Backside passivation effectively reduces the backside recombination of silicon wafers, increase the open-circuit voltage, and improves the conversion efficiency of a solar cell.

(9) Deposit an anti-reflection film on the front face of the silicon wafer for the second time.

The anti-reflection film is a silicon nitride film. The PECAD method is used to deposit the anti-reflection film. In an example, the deposition thickness is 50-80 nm, particularly 60-80 nm. The anti-reflection film on the front face effectively improves the absorption rate of solar energy and improves the conversion efficiency of a solar cell.

(10) Perform laser perforation on the back face of the silicon wafer.

For example, a DR laser is used to perforate the passivation film on the back face, so that ohmic contact is formed between the aluminum on the back face of the silicon wafer and the silicon substrate.

(11) Etch back electrode paste and aluminum paste on the back face of the silicon wafer; etch and dry positive electrode paste on the front face of the silicon wafer.

(12) Sinter the silicon wafer obtained in 11) at a temperature of 700-950° C., to form a back electrode, an aluminum back electric field, and a positive electrode, and obtain a selective passivation contact crystalline silicon solar cell product.

Correspondingly, the disclosure further discloses a selective passivation contact crystalline silicon solar cell, comprising: a silicon wafer; an anti-reflection film layer and a positive electrode arranged on a front face of the silicon wafer; and a passivation film, a back electrode, and a back electric field arranged on a back face of the silicon wafer.

A tunneling layer, a doped polysilicon layer, and an anti-reflection film layer are arranged between the positive electrode and the silicon wafer. In an embodiment, the positive electrode is in contact with the passivation tunneling layer through the anti-reflection film layer and the doped polysilicon layer.

The selective passivation contact crystalline silicon solar cell is prepared using the foregoing preparation method. The following provides a further description with reference to specific embodiments.

### Example 1

In this example, a method for preparing a selective passivation contact crystalline silicon solar cell is as follows:

(1) Form a textured surface on a front face of a silicon wafer: 800 pieces of P-type silicon wafers are selected as substrate materials; the wet etching technology is used to form a textured surface on a surface of the silicon wafer; the weight loss is controlled to be 0.55 g per piece and the reflectivity is 10.5%.

(2) Deposit a tunneling layer and a doped polysilicon layer on the textured surface of the silicon wafer: the LPCVD method is used for deposition; the tunneling layer is silicon dioxide; the doped polysilicon layer is phosphorus-doped N⁺ polysilicon; a thickness of the tunneling layer is 1 nm, and a thickness of the doped polysilicon layer is 20 nm.

(3) Deposit an anti-reflection film layer on the front face of the silicon wafer: the PECVD method is used for deposition; the anti-reflection film layer is silicon nitride; a thickness of the anti-reflection film layer is 10 nm.

(4) Remove the tunneling layer, the doped polysilicon layer, and the anti-reflection film layer in a non-electrode region on the front face of the silicon wafer by using a laser: a DR laser cutting machine is used to remove a film in a non-electrode region on the front face of the silicon wafer.

(5) Form a textured surface on the front face of the silicon wafer again: a mixed solution of NaOH, Na₂SiO₃, and isopropanol is used for etching to form a new textured surface in the non-electrode region; a weight of the silicon wafer is reduced by 0.15 g during texturing.

(6) Perform phosphorus diffusion on a surface of the silicon wafer: the low concentration diffusion technology is used to form a PN junction; a silicon wafer that has only been textured is used as a reference wafer, and the sheet resistance of the reference wafer after diffusion is 100 Ω/sq.

(7) Remove a PN junction on a back face and a periphery of the silicon wafer and phosphosilicate glass on the front face: an HF solution is used to remove the PN junction on the back face and the periphery of the silicon wafer and the phosphosilicate glass on the front face.

(8) Deposit a passivation film on the back face of the silicon wafer: the PECVD method is used for deposition; the passivation film comprises aluminum oxide and silicon nitride.

(9) Deposit an anti-reflection film on the front face of the silicon wafer for the second time: the PECVD method is used for deposition; the anti-reflection film is silicon nitride; a thickness of the anti-reflection film is 50 nm.

(10) Perform laser perforation on the back face of the silicon wafer: a DR laser cutting machine is used to perform perforation on the back face of the silicon wafer.

(11) Etch back electrode paste and aluminum paste on the back face of the silicon wafer; and etch positive electrode paste on the front face of the silicon wafer and dry.

(12) Sinter the silicon wafer obtained in 11) at a temperature of 700-950° C., to form a back electrode, an aluminum back electric field, and a positive electrode and obtain a selective passivation contact crystalline silicon solar cell product.

### Example 2

In this example, a method for preparing a selective passivation contact crystalline silicon solar cell is as follows:

(1) Form a textured surface on a front face of a silicon wafer: 800 pieces of P-type silicon wafers are selected as substrate materials; the wet etching technology is used to form a textured surface on a surface of the silicon wafer; the weight loss is controlled to be 0.85 g and the reflectivity is 11.5%.

(2) Deposit a tunneling layer and a doped polysilicon layer on the textured surface of the silicon wafer: the LPCVD method is used for deposition; the tunneling layer is silicon dioxide; the doped polysilicon layer is phosphorus-doped N⁻⁺ polysilicon; a thickness of the tunneling layer is 8 nm, and a thickness of the doped polysilicon layer is 100 nm.

(3) Deposit an anti-reflection film layer on the front face of the silicon wafer: the PECVD method is used for deposition; the anti-reflection film layer is silicon nitride; a thickness of the anti-reflection film layer is 40 nm.

(4) Remove the tunneling layer, the doped polysilicon layer, and the anti-reflection film layer in a non-electrode region on the front face of the silicon wafer by using a laser: a DR laser cutting machine is used to remove a film in a non-electrode region on the front face of the silicon wafer.

(5) Form a textured surface on the front face of the silicon wafer again: a mixed solution of NaOH, Na₂SiO₃, and isopropanol is used for etching to form a new textured surface in the non-electrode region; a weight of the silicon wafer is reduced by 0.35 g during texturing.

(6) Perform phosphorus diffusion on a surface of the silicon wafer: the low concentration diffusion technology is used to form a PN junction; a silicon wafer that has only been textured is used as a reference wafer, and the sheet resistance of the reference wafer after diffusion is 160 Ω/sq.

(7) Remove a PN junction on a back face and a periphery of the silicon wafer and phosphosilicate glass on the front face: an HF solution is used to remove the PN junction on the back face and the periphery of the silicon wafer and the phosphosilicate glass on the front face.

(8) Deposit a passivation film on the back face of the silicon wafer: the PECVD method is used for deposition; the passivation film comprises aluminum oxide and silicon nitride.

(9) Deposit an anti-reflection film on the front face of the silicon wafer for the second time: the PECVD method is used for deposition; the anti-reflection film is silicon nitride; a thickness of the anti-reflection film is 80 nm.

(10) Perform laser perforation on the back face of the silicon wafer: a DR laser cutting machine is used to perform perforation on the back face of the silicon wafer.

(11) Etch back electrode paste and aluminum paste on the back face of the silicon wafer; and etch positive electrode paste on the front face of the silicon wafer and dry.

(12) Sinter the silicon wafer obtained in 11) at a temperature of 700-950° C., to form a back electrode, an aluminum back electric field, and a positive electrode and obtain a selective passivation contact crystalline silicon solar cell product.

### Example 3

In this example, a method for preparing a selective passivation contact crystalline silicon solar cell is as follows:

(1) Form a textured surface on a front face of a silicon wafer: 800 pieces of P-type silicon wafers are selected as substrate materials; the wet etching technology is used to form a textured surface on a surface of the silicon wafer; the weight loss is controlled to be 0.65 g and the reflectivity is 11%.

(2) Deposit a tunneling layer and a doped polysilicon layer on the textured surface of the silicon wafer: the LPCVD method is used for deposition; the tunneling layer is silicon dioxide; the doped polysilicon layer is phosphorus-doped N⁺ polysilicon; a thickness of the tunneling layer is 2 nm, and a thickness of the doped polysilicon layer is 55 nm.

(3) Deposit an anti-reflection film layer on the front face of the silicon wafer: the PECVD method is used for deposition; the anti-reflection film layer is silicon nitride; a thickness of the anti-reflection film layer is 35 nm.

(4) Remove the tunneling layer, the doped polysilicon layer, and the anti-reflection film layer in a non-electrode region on the front face of the silicon wafer by using a laser: a DR laser cutting machine is used to remove a film in a non-electrode region on the front face of the silicon wafer.

(5) Form a textured surface on the front face of the silicon wafer again: a mixed solution of NaOH, Na₂SiO₃, and isopropanol is used for etching to form a new textured surface in the non-electrode region; a weight of the silicon wafer is reduced by 0.22 g during texturing.

(6) Perform phosphorus diffusion on a surface of the silicon wafer: the low concentration diffusion technology is used to form a PN junction; a silicon wafer that has only been textured is used as a reference wafer, and the sheet resistance of the reference wafer after diffusion is 135 Ω/sq.

(7) Remove a PN junction on a back face and a periphery of the silicon wafer and phosphosilicate glass on the front face: an HF solution is used to remove the PN junction on the back face and the periphery of the silicon wafer and the phosphosilicate glass on the front face.

(8) Deposit a passivation film on the back face of the silicon wafer: the PECVD method is used for deposition; the passivation film comprises aluminum oxide and silicon nitride.

(9) Deposit an anti-reflection film on the front face of the silicon wafer for the second time: the PECVD method is used for deposition; the anti-reflection film is silicon nitride; a thickness of the anti-reflection film is 65 nm.

(10) Perform laser perforation on the back face of the silicon wafer: a DR laser cutting machine is used to perform perforation on the back face of the silicon wafer.

(11) Etch back electrode paste and aluminum paste on the back face of the silicon wafer; and etch positive electrode paste on the front face of the silicon wafer and dry.

(12) Sinter the silicon wafer obtained in 1) at a temperature of 700-950° C., to form a back electrode, an aluminum back electric field, and a positive electrode and obtain a selective passivation contact crystalline silicon solar cell product.

### Example 4

In this example, a method for preparing a selective passivation contact crystalline silicon solar cell is as follows:

(1) Form a textured surface on a front face of a silicon wafer: 800 pieces of P-type silicon wafers are selected as substrate materials; the wet etching technology is used to form a textured surface on a surface of the silicon wafer; the weight loss is controlled to be 0.7 g and the reflectivity is 10.7%.

(2) Deposit a tunneling layer and a doped polysilicon layer on the textured surface of the silicon wafer: the LPCVD method is used for deposition; the tunneling layer is silicon dioxide; the doped polysilicon layer is phosphorus-doped N⁺ polysilicon; a thickness of the tunneling layer is 2.5 nm, and a thickness of the doped polysilicon layer is 65 nm.

(3) Deposit an anti-reflection film layer on the front face of the silicon wafer: the PECVD method is used for deposition; the anti-reflection film layer is silicon nitride; a thickness of the anti-reflection film layer is 30 nm.

(4) Remove the tunneling layer, the doped polysilicon layer, and the anti-reflection film layer in a non-electrode region on the front face of the silicon wafer by using a laser: a DR laser cutting machine is used to remove a film in a non-electrode region on the front face of the silicon wafer.

(5) Form a textured surface on the front face of the silicon wafer again: a mixed solution of NaOH, Na₂SiO₃, and isopropanol is used for etching to form a new textured surface in the non-electrode region; a weight of the silicon wafer is reduced by 0.25 g during texturing.

(6) Perform phosphorus diffusion on a surface of the silicon wafer: the low concentration diffusion technology is used to form a PN junction; a silicon wafer that has only been textured is used as a reference wafer, and the sheet resistance of the reference wafer after diffusion is 140 Ω/sq.

(7) Remove a PN junction on a back face and a periphery of the silicon wafer and phosphosilicate glass on the front face: an HF solution is used to remove the PN junction on the back face and the periphery of the silicon wafer and the phosphosilicate glass on the front face.

(8) Deposit a passivation film on the back face of the silicon wafer: the PECVD method is used for deposition; the passivation film comprises aluminum oxide and silicon nitride.

(9) Deposit an anti-reflection film on the front face of the silicon wafer for the second time: the PECVD method is used for deposition; the anti-reflection film comprises silicon nitride; a thickness of the anti-reflection film is 70 nm.

(10) Perform laser perforation on the back face of the silicon wafer: a DR laser cutting machine is used to perform perforation on the back face of the silicon wafer.

(11) Etch back electrode paste and aluminum paste on the back face of the silicon wafer; and etch positive electrode paste on the front face of the silicon wafer and dry.

(12) Sinter the silicon wafer obtained in 11) at a temperature of 700-950° C., to form a back electrode, an aluminum back electric field, and a positive electrode and obtain a selective passivation contact crystalline silicon solar cell product.

### Comparison Example 1

This example is divided into 11 steps. 1) to 3) are the same as those in Example 4 of the disclosure. 4) to 11) are the same as 5) to 12) in Example 4 of the disclosure.

The performances of the selective passivation contact crystalline silicon solar cells in Examples 1-4 and the comparison example are measured, and the results are shown in Table 1.

TABLE 1

| | J_{sc} (mA/cm²) | Efficiency (%) |
|---|---|---|
| Example 1 | 31 | 20.88 |
| Example 2 | 39 | 21.00 |
| Example 3 | 39 | 21.94 |
| Example 4 | 42 | 21.98 |
| Comparison | 22 | 20.05 |
| example 1 | | |

### Comparison Groups:

| | | | 1-sun Implied |
|---|---|---|---|
| Type | Lifetime (us) | Jo (A/cm²) | Voc (V) |
| POLO-PERC | 399.3 | 1.13E−14 | 0.731 |
| | 322.9 | 1.84E−14 | 0.718 |
| AVG | 361.1 | 1.48E−14 | 0.724 |
| BL | 189.2 | 1.13E−14 | 0.697 |
| | 170.9 | 4.70E−14 | 0.688 |
| AVG | 180.1 | 2.91E−14 | 0.692 |

Note: Lifetime is the minority carrier lifetime in solar cell; Jo is the recombinant carrier; 1-sun implied Voc represents the results of passivation performance test; the polo-perc with the tunneling layer is compared with the solar cell without adding the tunneling layer; I-Voc of the polo-perc with the tunneling layer is increased from 0.692 V to 0.724 V, and the current increases by 30 mV, indicating that the disclosure enhances the passivation performance (passivation is essentially anti-combination).

It can be seen from the table that the efficiency of the selective passivation contact crystalline silicon solar cell in the disclosure is increased by 0.8%-1.9%, and the efficiency is significantly improved.

The disclosure further relates to a crystalline silicon solar cell prepared using the foregoing method.

The disclosure further provides a crystalline silicon solar cell, comprising: a silicon wafer; and an anti-reflection film layer and a positive electrode arranged on a front face of the silicon wafer. A tunneling layer, a doped polysilicon layer, and an anti-reflection film layer are arranged between the positive electrode and the silicon wafer. In a region having no positive electrode on the front face of the silicon wafer, the anti-reflection film layer is in direct contact with the silicon wafer.

In some embodiments, the crystalline silicon solar cell further comprises a passivation film, a back electrode, and a back electric field arranged on a back face of the silicon wafer.

In some embodiments, the tunneling layer is an SiO₂ layer with a thickness of 0.5-8 nm; a thickness of the doped polysilicon layer is 5-250 nm. Particularly, a thickness of the tunneling layer is 0.5-3 nm; a thickness of the doped polysilicon layer is 50-150 nm.

In some embodiments, the anti-reflection film layer is deposited using a plasma chemical vapor deposition method, and the anti-reflection film layer is a silicon nitride film layer.

In some embodiments, the silicon wafer is a P-type monocrystalline silicon wafer; the doped polysilicon layer is a phosphorus-doped N⁺ type polysilicon layer.

In some embodiments, the passivation film comprises an aluminum oxide film and a silicon nitride film, and the aluminum oxide film is arranged between the silicon wafer and the silicon nitride film.

In some embodiments, the passivation film comprises an opening, and the back electric field is in contact with the silicon wafer through the opening.

It will be obvious to those skilled in the art that changes and modifications may be made, and therefore, the aim in the appended claims is to cover all such changes and modifications.

What is claimed is:

1. A method, comprising:
(1) forming a textured surface on a front face of a silicon wafer;
(2) depositing a tunneling layer and a doped polysilicon layer on the textured surface of the silicon wafer;
(3) depositing a first anti-reflection film layer on the front face of the silicon wafer; and
(4) removing the tunneling layer by a laser, the doped polysilicon layer, and the first anti-reflection film layer from a non-electrode region on the front face of the silicon wafer.

2. The method of claim 1, further comprising:
(5) forming a textured surface on the front face of the silicon wafer again;
(6) performing phosphorus diffusion on a surface of the silicon wafer;
(7) removing a PN junction on a back face and a periphery of the silicon wafer and phosphosilicate glass on the front face;
(8) depositing a passivation film on the back face of the silicon wafer;
(9) depositing a second anti-reflection film layer on the front face of the silicon wafer;
(10) performing laser perforation on the back face of the silicon wafer;
(11) etching back electrode paste and aluminum paste on the back face of the silicon wafer; and etching positive electrode paste on the front face of the silicon wafer and drying; and
(12) sintering the silicon wafer obtained in 11) at a temperature of 700-950° C., to form a back electrode, an aluminum back electric field, and a positive electrode.

3. The method of claim 1, wherein the tunneling layer is an SiO₂ layer with a thickness of 0.5-8 nm; and a thickness of the doped polysilicon layer is 5-250 nm.

4. The method of claim 3, wherein the thickness of the tunneling layer is 0.5-3 nm; and the thickness of the doped polysilicon layer is 50-150 nm.

5. The method of claim 3, wherein after 2) is completed, a sheet resistance of the silicon wafer is 40-160 Ω/sq.

6. The method of claim 1, wherein in 3), the first anti-reflection film layer is deposited using a plasma chemical vapor deposition method; the first anti-reflection film layer is a silicon nitride film layer with a thickness of 10-100 nm.

7. The method of claim 2, wherein the positive electrode is in contact with the tunneling layer through the doped polysilicon layer, the first anti-reflection film layer, and the second anti-reflection film layer.

8. The method of claim 1, wherein the silicon wafer is a P-type monocrystalline silicon wafer; and the doped polysilicon layer is a phosphorus-doped N⁺ type polysilicon layer.

9. The method of claim 2, wherein in 5), a mixed solution of NaOH, Na₂SiO₃, and isopropanol is used to etch the surface of the silicon wafer to prepare a textured surface.

10. The method of claim 1, wherein 4) is performed using a laser.

11. A crystalline silicon solar cell, being prepared using the method of claim 1.

12. A crystalline silicon solar cell, comprising: a silicon wafer; and an anti-reflection film layer and a positive electrode arranged on a front face of the silicon wafer;
wherein:
a tunneling layer, a doped polysilicon layer, and the anti-reflection film layer are arranged between the positive electrode and the silicon wafer; and
in a region having no positive electrode on the front face of the silicon wafer, the anti-reflection film layer is in direct contact with the silicon wafer.

13. The cell of claim 12, further comprising: a passivation film, a back electrode, and a back electric field arranged on a back face of the silicon wafer.

14. The cell of claim 12, wherein the tunneling layer is an SiO₂ layer with a thickness of 0.5-8 nm; and a thickness of the doped polysilicon layer is 5-250 nm.

15. The cell of claim 14, wherein the thickness of the tunneling layer is 0.5-3 nm; and the thickness of the doped polysilicon layer is 50-150 nm.

16. The cell of claim 12, wherein the anti-reflection film layer is deposited using a plasma chemical vapor deposition method, and the anti-reflection film layer is a silicon nitride film layer.

17. The cell of claim 12, wherein the silicon wafer is a P-type monocrystalline silicon wafer; and the doped polysilicon layer is a phosphorus-doped N⁺ type polysilicon layer.

18. The cell of claim 13, wherein the passivation film comprises an aluminum oxide film and a silicon nitride film, and the aluminum oxide film is arranged between the silicon wafer and the silicon nitride film.

19. The cell of claim 13, wherein the passivation film comprises an opening, and the back electric field is in contact with the silicon wafer through the opening.
